(19) United States
(12) Patent Application Publication
(10) Pub. No.: US 2023/0361019 A1
(43) Pub. Date: Nov. 9, 2023

(54) SEMICONDUCTOR DEVICE

(71) Applicant: NANYA TECHNOLOGY CORPORATION, New Taipei City (TW)

(72) Inventor: Fang-Wen LIU, New Taipei City (TW)

(21) Appl. No.: 17/661,749

(22) Filed: May 3, 2022

(51) Int. Cl. H01L 23/522; H01L 23/528; H01L 23/532

(52) U.S. Cl. CPC H01L 23/5223; H01L 23/5286; H01L 23/53214; H01L 23/53228

(57) ABSTRACT

The present disclosure provides a semiconductor device. The semiconductor device includes a wafer, powering redistribution layers, and grounding redistribution layers. The powering redistribution layers are disposed on the wafer. The grounding redistribution layers are disposed on the wafer, in which each of the powering redistribution layers and a corresponding one of the grounding redistributions layers form a capacitor.

### BACKGROUND

### Field of Invention

The present invention relates to a semiconductor device.

### Description of Related Art

A decoupling capacitor is used to decouple one part of a circuit from another. Noise caused by other circuit elements is shunted through the capacitor, reducing the effect it has on the rest of the circuit. The operation of high-speed integrated circuits can be affected by the electrical noise generated by the continuous switching of the transistors located in the circuit. It is well known that the inductive noise of an integrated circuit can be reduced by connecting decoupling capacitors to the circuit. Decoupling capacitors placed on power-consuming circuits are able to smooth out voltage variations with the stored charge on the decoupling capacitor. The stored charge is used as a local power supply to device inputs during signal switching stages, allowing the decoupling capacitor to mitigate the effects of voltage noise induced into the system by parasitic inductance. As layout area limited in advanced process, the space for decoupling capacitor is reducing. To increase ability of noise immunity, the number of decoupling capacitor should be increased.

### SUMMARY

In view of this, one purpose of present disclosure is to provide a semiconductor device that can solve the aforementioned problems.

In order to achieve the above objective, according to an embodiment of the present disclosure, a semiconductor device includes a wafer, powering redistribution layers, and grounding redistribution layers. The powering redistribution layers are disposed on the wafer. The grounding redistribution layers are disposed on the wafer, in which each of the powering redistribution layers and a corresponding one of the grounding redistributions layers form a capacitor.

In one or more embodiments of the present disclosure, the powering redistribution layers and the grounding redistribution layers are alternatively arranged.

In one or more embodiments of the present disclosure, the semiconductor device further includes central pads respectively disposed in centers of the powering redistribution layers and the grounding redistribution layers.

In one or more embodiments of the present disclosure, the semiconductor device further includes redistribution pads respectively disposed on opposite ends of the powering redistribution layers and on opposite ends of the grounding redistribution layers.

In one or more embodiments of the present disclosure, a material of the powering redistribution layers is identical to a material of the grounding redistribution layers.

In one or more embodiments of the present disclosure, a material of the powering redistribution layers and a material of the grounding redistribution layers comprise aluminum or copper.

In one or more embodiments of the present disclosure, the powering redistribution layers and the grounding redistribution layers are elongated in a first direction and alternatively arranged in a second direction.

In one or more embodiments of the present disclosure, the first direction is perpendicular to the second direction.

In one or more embodiments of the present disclosure, each of the powering redistribution layers and the grounding redistribution layers are bar-shaped.

In order to achieve the above objective, according to an embodiment of the present disclosure, a semiconductor device includes a wafer, powering redistribution layers, and grounding redistribution layers. The powering redistribution layers are disposed on the wafer. The grounding redistribution layers are disposed on the wafer. Each of the powering redistribution layers and a corresponding one of the grounding redistribution layers form a capacitor, and the powering redistribution layers and the grounding redistribution layers are bar-shaped.

In one or more embodiments of the present disclosure, the semiconductor device further includes powering bridges alternatively connecting first ends of two of the powering redistribution layers and second ends of two of the powering redistribution layers, such that each of the powering bridges and a corresponding one of the grounding redistribution layers form a capacitor.

In one or more embodiments of the present disclosure, each of the grounding redistribution layers is surrounded by the two of the powering redistribution layers and one of the powering bridges on three sides.

In one or more embodiments of the present disclosure, the semiconductor device further includes grounding bridges alternatively connecting first ends of two of the grounding redistribution layers and second ends of two of the grounding redistribution layers, such that each of the grounding bridges and a corresponding one of the powering redistribution layers form a capacitor.

In one or more embodiments of the present disclosure, each of the powering redistribution layers is surrounded by the two of the grounding redistribution layers and one of the grounding bridges on three sides.

In one or more embodiments of the present disclosure, the semiconductor device further includes powering bridges consecutively connecting first ends of the powering redistribution layers and grounding bridges consecutively connecting second ends of the grounding redistribution layers. Each of the powering bridges and a corresponding one of the grounding redistribution layers form a capacitor, and each of the grounding bridges and a corresponding one of the powering redistribution layers form a capacitor.

In one or more embodiments of the present disclosure, the semiconductor device further includes powering bridges consecutively connecting second ends of the powering redistribution layers and grounding bridges consecutively connecting first ends of the grounding redistribution layers. Each of the powering bridges and a corresponding one of the grounding redistribution layers form a capacitor, and each of the grounding bridges and a corresponding one of the powering redistribution layers form a capacitor.

In one or more embodiments of the present disclosure, the powering redistribution layers and the grounding redistribution layers are elongated in a first direction and alternatively arranged in a second direction, and the first direction is perpendicular to the second direction.

In order to achieve the above objective, according to an embodiment of the present disclosure, a semiconductor device includes a wafer, powering redistribution layers, and grounding redistribution layers. The powering redistribution layers are disposed on the wafer. The grounding redistribution layers are disposed on the wafer. Each of the powering redistribution layers and a corresponding one of the grounding redistribution layers form a capacitor, and the powering redistribution layers and the grounding redistribution layers are concentrically disposed.

In one or more embodiments of the present disclosure, the powering redistribution layers and the grounding redistribution layers are alternatively arranged

In one or more embodiments of the present disclosure, the powering redistribution layers and the grounding redistribution layers are donut-shaped.

In summary, In the semiconductor device of present disclosure, since the redistribution layer extends from the central pad to the redistribution pads, such that the routing mobility of conductive lines and the convenience of performing electrical test are enhanced. In the semiconductor device of present disclosure, the semiconductor device provides additional metal capacitors and does not require additional masks and metal layers. The semiconductor device of the present disclosure can be realized in every generation.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a top view of a semiconductor device in accordance with an embodiment of present disclosure;

FIG. 2 is a cross-sectional view of the semiconductor device shown in FIG. 1 in accordance with an embodiment of present disclosure;

FIG. 3 is a side view of the semiconductor device electrically connected to a circuit board in accordance with an embodiment of present disclosure;

FIG. 4 is a schematic view of a powering redistribution layer and a grounding redistribution layer in accordance with an embodiment of present disclosure;

FIG. 5 is a top view of a plurality of powering redistribution layers and a plurality of grounding redistribution layers of the semiconductor device in accordance with an embodiment of present disclosure;

FIG. 6 is a top view of the plurality of powering redistribution layers with powering bridges and the grounding redistribution layers of the semiconductor device in accordance with an embodiment of present disclosure;

FIG. 7 is a top view of the powering redistribution layers and the grounding redistribution layers with grounding bridges of the semiconductor device in accordance with an embodiment of present disclosure;

FIG. 8 is a top view of the powering redistribution layers with powering bridges and the grounding redistribution layers with grounding bridges of the semiconductor device in accordance with an embodiment of present disclosure; and

FIG. 9 is a top view of the powering redistribution layers and the grounding redistribution layers of the semiconductor device in accordance with an embodiment of present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The redistribution layer (RDL) technologies utilize wire bonding with flip-chip to create smaller packaging, higher I/O count and better thermal, electrical, and reliability performance than conventional wire bonding technologies. For better performance of resist noise from outer circuit, the powering/grounding RDL is routed with metal capacitor to increase decoupling capacitance. A decoupling capacitor can be inserted between the metals with the back-end RDL interconnection.

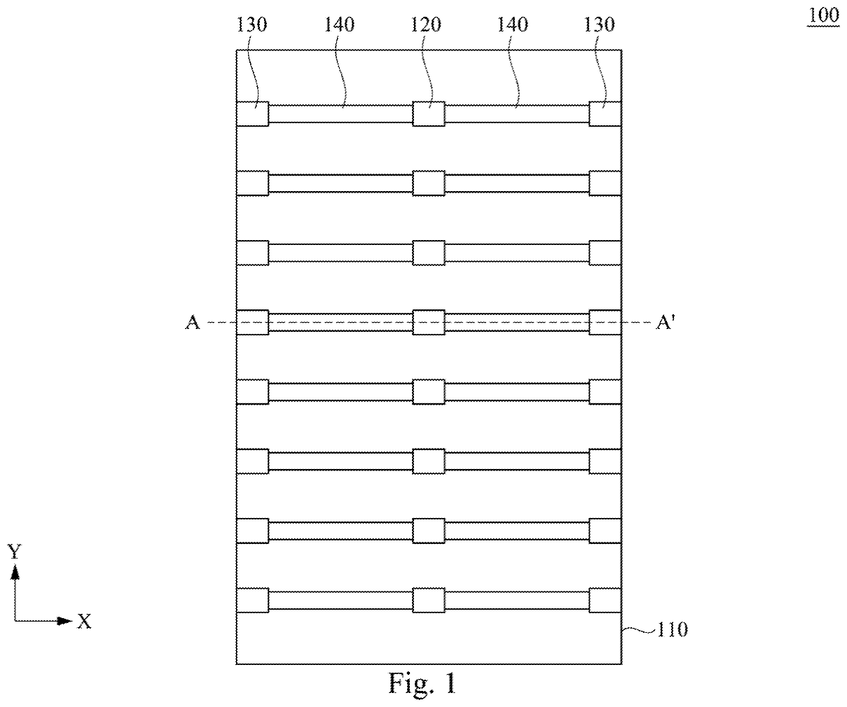

Reference is made to FIG. 1. FIG. 1 is a top view of a semiconductor device 100 in accordance with an embodiment of present disclosure. As shown in FIG. 1, the semiconductor device 100 is provided. The semiconductor device 100 includes a wafer 110, central pads 120, redistribution pads 130, and redistribution layers 140. As shown in FIG. 1, the central pads 120, the redistribution pads 130, and the redistribution layers 140 are disposed over the wafer 110.

More specifically, the wafer 110 includes a silicon-based substrate (not shown) and an integrated circuit (not shown) on the silicon-based substrate. The central pads 120 are electrically connected to the integrated circuit.

As shown in FIG. 1, the central pads 120 are central relative to the wafer 110 in a direction (for example, in x-direction) and arranged in another direction (for example, in y-direction), but the present disclosure is not limited thereto.

As shown in FIG. 1, for example, the redistribution pads 130 are located on edge of the wafer 110, but the present disclosure is not limited thereto. In some embodiments, a quantity of the redistribution pads 130 on the opposite ends of each redistribution layer 140 may be two, but the present disclosure is not limited thereto.

In some embodiments, the central pads 120 and the redistribution pads 130 are electrical testing pads.

As shown in FIG. 1, each of the redistribution layers 140 is connected between the redistribution pads 130 and through the central pad 120.

In some embodiments, the redistribution layers 140 are elongated in a direction (for example, in x-direction) and arranged in another direction (for example, in y-direction), but the present disclosure is not limited thereto. In some embodiments, the redistribution layers 140 may be used as a power terminal or a ground terminal. For example, as shown in FIG. 1, the redistribution layers 140 used as the power terminal and the ground terminal are alternatively arranged in y-direction, such that each of the redistribution layers 140 used as the power terminal and each of the redistribution layers 140 used as the ground terminal forms a capacitor.

As shown in FIG. 1, the central pads 120 are located in the center of the redistribution layers 140, and the redistribution pads 130 are on opposite ends of the redistribution layers 140. In other words, each of the redistribution layers 140 is configured with a central pad 120 and two redistribution pads 130 on the edge of the wafer 110, for example.

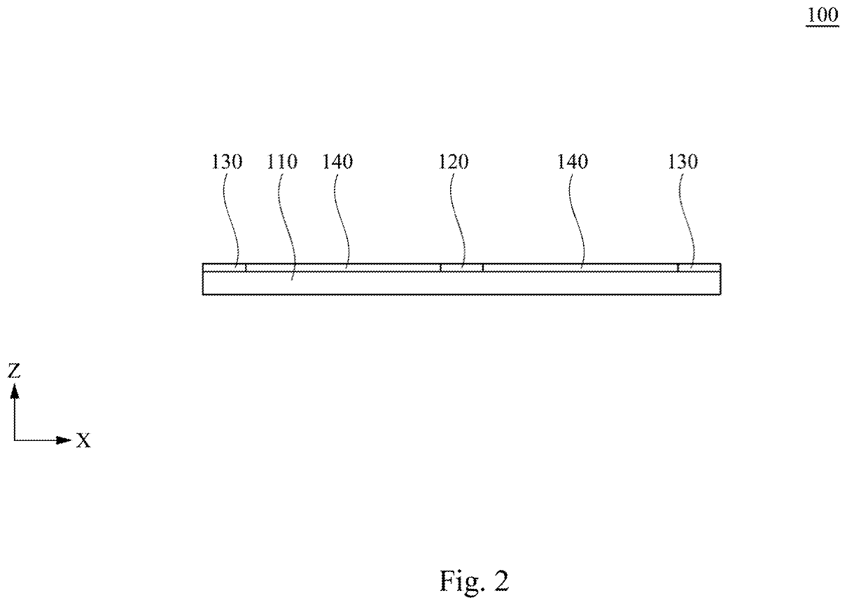

Reference is made to FIG. 2. FIG. 2 is a cross-sectional view of the semiconductor device 100 in accordance with an embodiment of present disclosure based on a section A-A′ of FIG. 1. In this embodiment, the central pads 120 and the redistribution pads 130 are located on the wafer 110. In some embodiments, as shown in FIG. 2, the central pads 120, the redistribution pads 130, and the redistribution layers 140 are disposed on the wafer 110.

In some embodiments, the wafer 110 may include a material, such as polysilicon, monocrystalline silicon or amorphous silicon. However, any suitable material may be utilized.

In some embodiments, the central pads 120 and the redistribution pads 130 may include a material, such as aluminum (Al) or copper (Cu). However, any suitable material may be utilized.

In some embodiments, central pads 120 and the redistribution pads 130 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming central pads 120 and the redistribution pads 130.

In some embodiments, the redistribution layers 140 may include a material, such as aluminum (Al) or copper (Cu). However, any suitable material may be utilized.

In some embodiments, the wafer 140 may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the redistribution layers 140.

With the aforementioned structural configuration, the integrated circuits of wafer 110 may be electrically connected to the central pads 120, and the central pads 120 may be electrically connected to the redistribution pads 130 by the redistribution layers 140, such that the integrated circuits may extend from the central pads 120 to the redistribution pads 130, thereby enhancing the routing mobility of conductive lines and the convenience of performing electrical test.

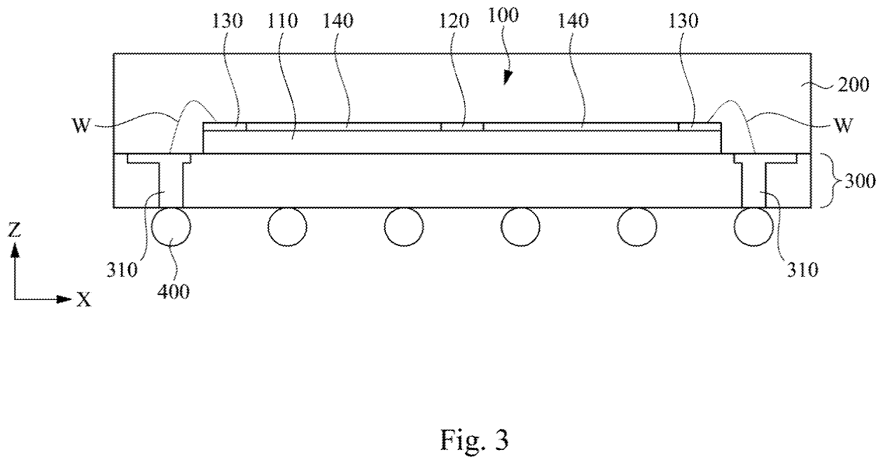

Reference is made to FIG. 3. FIG. 3 is a side view of the semiconductor device 100 electrically connected to a circuit board 300, in accordance with an embodiment of present disclosure. As shown in FIG. 3, the semiconductor device 100, a package material 200, a circuit board 300, and a plurality of solder balls 400 are provided. The package material 200 at least covers the semiconductor device 100. The semiconductor device 100 is disposed on the circuit board 300, and the semiconductor device 100 is electrically connected to the circuit board 300 by wires W. In this embodiment, the circuit board 300 includes a plurality of contacts 310. More specifically, the wires W connect the redistribution pads 130 and the contacts 310, as shown in FIG. 3. The solder balls 400 are disposed under the circuit board 300, and are configured to connect automated testing equipment (not shown).

In some embodiments, the package material 200 may include a material, such as epoxy. However, any suitable material may be utilized.

In some embodiments, the circuit board 300 may be a printed circuit board (PCB).

In some embodiments, the solder balls 400 may be tin-based solder balls.

In some embodiments, the solder balls 400 may include a material, such as tin-based material. However, any suitable material may be utilized.

With the aforementioned structural configuration, the wafer 110 is electrically connected to the circuit board 300, and the circuit board 300 is electrically connected to the automated testing equipment through the solder balls 400, such that the electric current provided by the automated testing equipment can conduct the redistribution layers 140 which are used as power terminals and grounding terminals, thereby forming a capacitance between the redistribution layers 140.

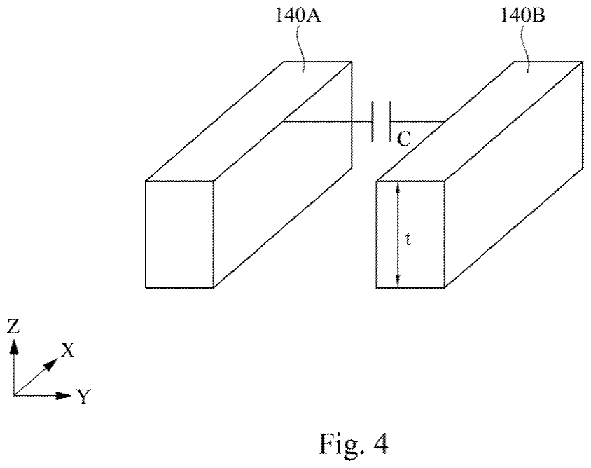

Reference is made to FIG. 4. FIG. 4 is a schematic view of a powering redistribution layer 140A and a grounding redistribution layer 140B in accordance with an embodiment of present disclosure. As shown in FIG. 4, the redistribution layers 140 include the powering redistribution layer 140A and the grounding redistribution layer 140B. In this embodiment, the powering redistribution layer 140A and the grounding redistribution layer 140B are respectively used as the powering terminal and the grounding terminal. Hence, as shown in FIG. 4, both the powering redistribution layer 140A and the grounding redistribution layer 140B forms a capacitor, thereby generating a capacitance C in between.

In some embodiments, as shown in FIG. 4, the powering redistribution layer 140A and the grounding redistribution layer 140B are elongated in a direction (for example, in x-direction) and arranged in another direction (for example, in y-direction).

In some embodiments, each of the powering redistribution layers 140A and the grounding redistribution layers 140B include a thickness t along a direction (for example, in z-direction), and the thickness t is in a range from about 4 μm to about 5 μm, but the present disclosure is not limited thereto.

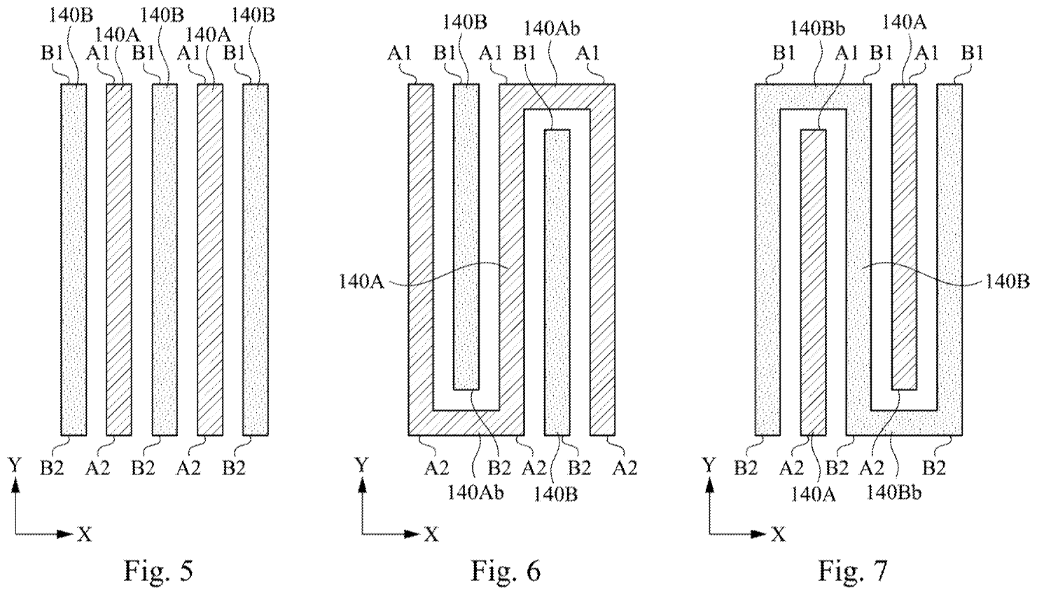

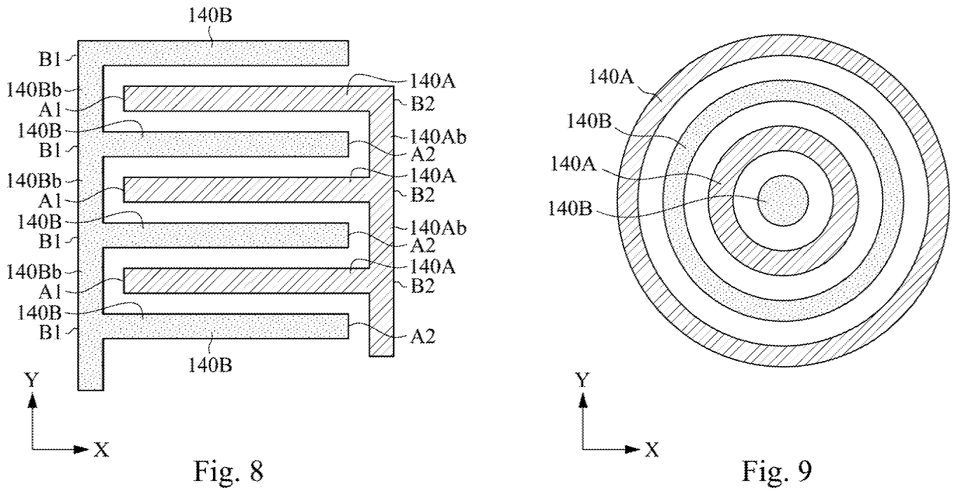

The following describes various embodiments of the configuration of powering redistribution layers 140A and grounding redistribution layers 140B. Please refer to FIG. 5, FIG. 6, FIG. 7, FIG. 8, and FIG. 9 for better understanding the various embodiments of the configuration of the powering redistribution layers 140A and the grounding redistribution layers 140B.

Reference is made to FIG. 5. FIG. 5 shows a configuration of the powering redistribution layers 140A and the grounding redistribution layers 140B in accordance with an embodiment of present disclosure. As shown in FIG. 5, powering redistribution layers 140A and grounding redistribution layers 140B are provided. Each of the powering redistribution layers 140A includes a first end A1 and a second end A2. Each of the grounding redistribution layers 140B includes a first end B1 and a second end B2. In this embodiment, the powering redistribution layers 140A and the grounding redistribution layers 140B are alternatively arranged. As shown in FIG. 5, each of the powering redistribution layers 140A and a corresponding one of the grounding redistribution layers 140B form a capacitor.

In some embodiments, as shown in FIG. 5, the powering redistribution layers 140A and the grounding redistribution layers 140B are elongated in a direction (for example, in y-direction) and alternatively arranged in another direction (for example, in x-direction), but the present disclosure is not limited thereto. In some embodiments, the powering redistribution layers 140A and the grounding redistribution layers 140B are elongated in a direction (for example, in x-direction) and alternatively arranged in another direction (for example, in y-direction).

In some embodiments, as shown in FIG. 5, the direction in which the powering redistribution layers 140A and the grounding redistribution layers 140B are elongated is perpendicular to the another direction in which the powering redistribution layers 140A and the grounding redistribution layers 140B are arranged, but the present disclosure is not limited thereto.

In some embodiments, the powering redistribution layers 140A and the grounding redistribution layers 140B may include a material, such as aluminum (Al) or copper (Cu). However, any suitable material may be utilized.

In some embodiments, the material of the powering redistribution layers 140A is identical to the material of the grounding redistribution layers 140B.

In some embodiments, the powering redistribution layers 140A and the grounding redistribution layers 140B may be formed by any suitable method, for example, CVD (chemical vapor deposition), PECVD (plasma-enhanced chemical vapor deposition), PVD (physical vapor deposition), ALD (atomic layer deposition), PEALD (plasma-enhanced atomic layer deposition), ECP (electrochemical plating), electroless plating, or the like. The present disclosure is not intended to limit the methods of forming the powering redistribution layers 140A and the grounding redistribution layers 140B.

In some embodiments, as shown in FIG. 5, the powering redistribution layers 140A and the grounding redistribution layers 140B are bar-shaped. The present disclosure is not intended to limit the aforementioned shape of the powering redistribution layers 140A and the grounding redistribution layers 140B.

Reference is made to FIG. 6. FIG. 6 shows a configuration of the powering redistribution layers 140A and the grounding redistribution layers 140B in accordance with an embodiment of present disclosure. As shown in FIG. 6, powering redistribution layers 140A and grounding redistribution layers 140B are provided. The powering redistribution layers 140A and the grounding redistribution layers 140B of FIG. 6 are similar to that of FIG. 5. The configuration shown in FIG. 6 further includes powering bridges 140Ab relative to the configuration shown in FIG. 5. In this embodiment, the powering redistribution layers 140A and the grounding redistribution layers 140B are alternatively arranged, and the powering bridges 140Ab alternatively connect the first ends A1 of two powering redistribution layers 140A and the second ends A2 of two powering redistribution layers 140A, such that each of the powering redistribution layers 140A and a corresponding one of the grounding redistribution layers 140B form a capacitor, and each of the powering bridges 140Ab and a corresponding one of the grounding redistribution layers 140B also form a capacitor, as shown in FIG. 6.

In some embodiments, as shown in FIG. 6, the powering redistribution layers 140A and the grounding redistribution layers 140B are elongated in a direction (for example, in y-direction) and alternatively arranged in another direction (for example, in x-direction), but the present disclosure is not limited thereto. In some embodiments, the powering redistribution layers 140A and the grounding redistribution layers 140B are elongated in a direction (for example, in x-direction) and alternatively arranged in another direction (for example, in y-direction).

In some embodiments, as shown in FIG. 6, the direction in which the powering redistribution layers 140A and the grounding redistribution layers 140B are elongated is perpendicular to the another direction in which the powering redistribution layers 140A and the grounding redistribution layers 140B are arranged, but the present disclosure is not limited thereto.

In some embodiments, as shown in FIG. 6, the powering redistribution layers 140A and the grounding redistribution layers 140B are bar-shaped. The present disclosure is not intended to limit the aforementioned shape of the powering redistribution layers 140A and the grounding redistribution layers 140B.

In some embodiments, as shown in FIG. 6, each of the grounding redistribution layers 140B is surrounded by two powering redistribution layers 140A and one of the powering bridges 140Ab on three sides.

Reference is made to FIG. 7. FIG. 7 shows a configuration of the powering redistribution layers 140A and the grounding redistribution layers 140B in accordance with an embodiment of present disclosure. As shown in FIG. 7, powering redistribution layers 140A and grounding redistribution layers 140B are provided. The powering redistribution layers 140A and the grounding redistribution layers 140B of FIG. 7 are similar to that of FIG. 5. The configuration shown in FIG. 7 further includes grounding bridges 140Bb relative to the configuration shown in FIG. 5. In this embodiment, the powering redistribution layers 140A and the grounding redistribution layers 140B are alternatively arranged, and the grounding bridges 140Bb alternatively connect the first ends B1 of two grounding redistribution layers 140B and the second ends B2 of two grounding redistribution layers 140B, such that each of the powering redistribution layers 140A and a corresponding one of the grounding redistribution layers 140B form a capacitor, and each of the grounding bridges 140Bb and a corresponding one of the powering redistribution layers 140A also form a capacitor, as shown in FIG. 7.

In some embodiments, as shown in FIG. 7, the powering redistribution layers 140A and the grounding redistribution layers 140B are elongated in a direction (for example, in y-direction) and alternatively arranged in another direction (for example, in x-direction), but the present disclosure is not limited thereto. In some embodiments, the powering redistribution layers 140A and the grounding redistribution layers 140B are elongated in a direction (for example, in x-direction) and alternatively arranged in another direction (for example, in y-direction).

In some embodiments, as shown in FIG. 7, the direction in which the powering redistribution layers 140A and the grounding redistribution layers 140B are elongated is perpendicular to the another direction in which the powering redistribution layers 140A and the grounding redistribution layers 140B are arranged, but the present disclosure is not limited thereto.

In some embodiments, as shown in FIG. 7, the powering redistribution layers 140A and the grounding redistribution layers 140B are bar-shaped. The present disclosure is not intended to limit the aforementioned shape of the powering redistribution layers 140A and the grounding redistribution layers 140B.

In some embodiments, as shown in FIG. 7, each of the powering redistribution layers 140A is surrounded by two grounding redistribution layers 140B and one of the grounding bridges 140Bb on three sides.

Reference is made to FIG. 8. FIG. 8 shows a configuration of the powering redistribution layers 140A and the grounding redistribution layers 140B in accordance with an embodiment of present disclosure. As shown in FIG. 8, powering redistribution layers 140A and grounding redistribution layers 140B are provided. The powering redistribution layers 140A and the grounding redistribution layers 140B of FIG. 8 are similar to that of FIG. 5. The configuration shown in FIG. 8 further includes powering bridges 140Ab and grounding bridges 140Bb relative to the configuration shown in FIG. 5. In this embodiment, the powering redistribution layers 140A and the grounding redistribution layers 140B are alternatively arranged, the powering bridges 140Ab consecutively connect the first ends A1 of the powering redistribution layers 140A, and the grounding bridges 140Bb consecutively connect the second ends B2 of the grounding redistribution layers 140B. Therefore, each of the powering redistribution layers 140A and a corresponding one of the grounding redistribution layers 140B form a capacitor, each of the powering bridges 140Ab and a corresponding one of the grounding redistribution layers 140B also form a capacitor, and each of the grounding bridges 140Bb and a corresponding one of the powering redistribution layers 140A also form a capacitor, as shown in FIG. 8.

In some other embodiments, the powering redistribution layers 140A and the grounding redistribution layers 140B are alternatively arranged, the powering bridges 140Ab consecutively connect the second ends A2 of the powering redistribution layers 140A, and the grounding bridges 140Bb consecutively connect the first ends B1 of the grounding redistribution layers 140B.

In some embodiments, as shown in FIG. 8, the powering redistribution layers 140A and the grounding redistribution layers 140B are elongated in a direction (for example, in x-direction) and alternatively arranged in another direction (for example, in y-direction), but the present disclosure is not limited thereto. In some embodiments, the powering redistribution layers 140A and the grounding redistribution layers 140B are elongated in a direction (for example, in y-direction) and alternatively arranged in another direction (for example, in x-direction).

In some embodiments, as shown in FIG. 8, the direction in which the powering redistribution layers 140A and the grounding redistribution layers 140B are elongated is perpendicular to the another direction in which the powering redistribution layers 140A and the grounding redistribution layers 140B are arranged, but the present disclosure is not limited thereto.

In some embodiments, as shown in FIG. 8, the powering redistribution layers 140A and the grounding redistribution layers 140B are bar-shaped. The present disclosure is not intended to limit the aforementioned shape of the powering redistribution layers 140A and the grounding redistribution layers 140B.

In some embodiments, as shown in FIG. 8, each of the powering redistribution layers 140A is surrounded by two grounding redistribution layers 140B and one of the grounding bridges 140Bb on three sides, and each of the grounding redistribution layers 140B is surrounded by two powering redistribution layers 140A and one of the powering bridges 140Ab on three sides.

Reference is made to FIG. 9. FIG. 9 shows a configuration of the powering redistribution layers 140A and the grounding redistribution layers 140B in accordance with an embodiment of present disclosure. As shown in FIG. 9, powering redistribution layers 140A and grounding redistribution layers 140B are provided. In this embodiment, the powering redistribution layers 140A and the grounding redistribution layers 140B are alternatively arranged, and the powering redistribution layers 140A and the grounding redistribution layers 140B are concentrically disposed. As shown in FIG. 9, each of the powering redistribution layers 140A and each of the grounding redistribution layers 140B form a capacitor.

In some embodiments, one of the grounding redistribution layers 140B is formed in the center of the concentric circles formed by the powering redistribution layers 140A and the grounding redistribution layers 140B, as shown in FIG. 9.

In some other embodiments, one of the powering redistribution layers 140A is formed in the center of the concentric circles formed by the powering redistribution layers 140A and the grounding redistribution layers 140B.

In some embodiments, as shown in FIG. 9, the powering redistribution layers 140A and the grounding redistribution layers 140B are donut-shaped. The present disclosure is not intended to limit the aforementioned shape of the powering redistribution layers 140A and the grounding redistribution layers 140B.

Based on the above discussions, it can be seen that the semiconductor device 100 shown in FIG. 1, FIG. 2, and FIG. 3 and the configurations of the powering redistribution layers 140A and the grounding redistribution layers 140B shown in FIG. 5, FIG. 6, FIG. 7, FIG. 8, and FIG. 9 of the present disclosure offers advantages. It is understood, however, that other embodiments may offer additional advantages, and not all advantages are necessarily disclosed herein, and that no particular advantages are required for all embodiments. One advantage is that since the redistribution layer extends from the central pad to the redistribution pads, such that the routing mobility of conductive lines and the convenience of performing electrical test are enhanced. Another advantage is that the semiconductor device of present disclosure provides additional metal capacitors and does not require additional masks and metal layers. The semiconductor device of the present disclosure can be realized in every generation.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A semiconductor device, comprising:
a wafer;
a plurality of powering redistribution layers disposed on the wafer; and
a plurality of grounding redistribution layers disposed on the wafer,
wherein each of the powering redistribution layers and a corresponding one of the grounding redistributions layers form a capacitor.

2. The semiconductor device of claim 1, wherein the powering redistribution layers and the grounding redistribution layers are alternatively arranged.

3. The semiconductor device of claim 1, further comprising a plurality of central pads respectively disposed in centers of the powering redistribution layers and the grounding redistribution layers.

4. The semiconductor device of claim 1, further comprising a plurality of redistribution pads respectively disposed on opposite ends of the powering redistribution layers and on opposite ends of the grounding redistribution layers.

5. The semiconductor device of claim 1, wherein a material of the powering redistribution layers is identical to a material of the grounding redistribution layers.

6. The semiconductor device of claim 1, wherein a material of the powering redistribution layers and a material of the grounding redistribution layers comprise aluminum or copper.

7. The semiconductor device of claim 1, wherein the powering redistribution layers and the grounding redistribution layers are elongated in a first direction and alternatively arranged in a second direction.

8. The semiconductor device of claim 7, wherein the first direction is perpendicular to the second direction.

9. The semiconductor device of claim 1, wherein each of the powering redistribution layers and the grounding redistribution layers are bar-shaped.

10. A semiconductor device, comprising:
a wafer;
a plurality of powering redistribution layers disposed on the wafer; and
a plurality of grounding redistribution layer disposed on the wafer,
wherein each of the powering redistribution layers and a corresponding one of the grounding redistribution layers form a capacitor, and the powering redistribution layers and the grounding redistribution layers are bar-shaped.

11. The semiconductor device of claim 10, further comprising a plurality of powering bridges alternatively connecting first ends of two of the powering redistribution layers and second ends of two of the powering redistribution layers, such that each of the powering bridges and a corresponding one of the grounding redistribution layers form a capacitor.

12. The semiconductor device of claim 11, wherein each of the grounding redistribution layers is surrounded by the two of the powering redistribution layers and one of the powering bridges on three sides.

13. The semiconductor device of claim 10, further comprising a plurality of grounding bridges alternatively connecting first ends of two of the grounding redistribution layers and second ends of two of the grounding redistribution layers, such that each of the grounding bridges and a corresponding one of the powering redistribution layers form a capacitor.

14. The semiconductor device of claim 13, wherein each of the powering redistribution layers is surrounded by the two of the grounding redistribution layers and one of the grounding bridges on three sides.

15. The semiconductor device of claim 10, further comprising:
a plurality of powering bridges consecutively connecting first ends of the powering redistribution layers; and
a plurality of grounding bridges consecutively connecting second ends of the grounding redistribution layers,
wherein each of the powering bridges and a corresponding one of the grounding redistribution layers form a capacitor, and each of the grounding bridges and a corresponding one of the powering redistribution layers form a capacitor.

16. The semiconductor device of claim 10, further comprising:
a plurality of powering bridges consecutively connecting second ends of the powering redistribution layers; and
a plurality of grounding bridges consecutively connecting first ends of the grounding redistribution layers,
wherein each of the powering bridges and a corresponding one of the grounding redistribution layers form a capacitor, and each of the grounding bridges and a corresponding one of the powering redistribution layers form a capacitor.

17. The semiconductor device of claim 10, wherein the powering redistribution layers and the grounding redistribution layers are elongated in a first direction and alternatively arranged in a second direction, and the first direction is perpendicular to the second direction.

18. A semiconductor device, comprising:
a wafer;
a plurality of powering redistribution layers disposed on the wafer; and
a plurality of grounding redistribution layer disposed on the wafer,
wherein each of the powering redistribution layers and a corresponding one of the grounding redistribution layers form a capacitor, and the powering redistribution layers and the grounding redistribution layers are concentrically disposed.

19. The semiconductor device of claim 18, wherein the powering redistribution layers and the grounding redistribution layers are alternatively arranged.

20. The semiconductor device of claim 18, wherein the powering redistribution layers and the grounding redistribution layers are donut-shaped.
